(19) United States
(12) Patent Application Publication
(10) Pub. No.: US 2015/0187610 A1
(43) Pub. Date: Jul. 2, 2015

(54) SUBSTRATE PROCESSING APPARATUS, METHOD OF MANUFACTURING SEMICONDUCTOR DEVICE, AND NON-TRANSITORY COMPUTER-READABLE RECORDING MEDIUM

(71) Applicant: Hitachi Kokusai Electric Inc., Tokyo (JP)

(72) Inventor: Shuhei SAIDO, Toyama-shi (JP)

(73) Assignee: HITACHI KOKUSAI ELECTRIC INC., Tokyo (JP)

(21) Appl. No.: 14/191,133

(22) Filed: Feb. 26, 2014

(30) Foreign Application Priority Data
Dec. 27, 2013 (JP) 2013-271925

(51) Int. Cl. H01L 21/67; F17D 1/02

(52) U.S. Cl. CPC H01L 21/67017; H01L 21/67069; H01L 21/67242; F17D 1/02

(57) ABSTRACT

A substrate processing apparatus includes a common pipe connected to a process container wherethrough a first and second process gases flow; a buffer unit connected to an upstream side of the common pipe and having a width greater than a diameter of the common pipe; a first supply pipe wherethrough the first process gas flows, connected to a first surface of the buffer unit where the common pipe is connected or a second surface of the buffer unit opposite to the first surface; and a second supply pipe wherethrough the second process gas flows, connected to the first or second surface. Each of the first and second supply pipes is installed outer than the common pipe, and a distance between the first and second surfaces is shorter than a distance between a center axis of the common pipe and that of the first or second supply pipe.

### CROSS-REFERENCE TO RELATED PATENT APPLICATION

This U.S. non-provisional patent application claims priority under 35 U.S.C. §119 of Japanese Patent Application No. 2013-271925 filed on Dec. 27, 2013 in the Japanese Patent Office, the entire contents of which are hereby incorporated by reference.

### BACKGROUND OF THE INVENTION

1. Field of the Invention

The present invention relates to a substrate processing apparatus, a method of manufacturing a semiconductor device, and a recording medium.

2. Description of the Related Art

A single-wafer-type substrate processing apparatus has been known as a substrate processing apparatus, such as a semiconductor fabrication apparatus, etc. In the single-wafer-type substrate processing apparatus, an apparatus configured to supply a plurality of process gases from one gas supply pipe connected to a process container for processing a substrate has been known (for example, refer to Patent document 1: Japanese Patent Laid-open Publication No. 2012-164736).

### SUMMARY OF THE INVENTION

In an apparatus configured to supply a plurality of process gases from one gas supply pipe (hereinafter referred to as a ‘common pipe’) connected to a process container, supply pipes of the respective process gases are connected to an upstream side of the common pipe. When gases are simultaneously supplied from the supply pipes of the respective process gases, the gases supplied from the respective supply pipes are preferably mixed before the gases reach the process container to inhibit occurrence of a concentration gradient in the gases supplied into the process container. Here, the gases simultaneously supplied from the respective supply pipes may be different process gases or be process gases and inert gases.

It is a main object of the present invention to provide a substrate processing apparatus, a method of manufacturing a semiconductor device, and a recording medium, which may mix gases supplied from a plurality of supply pipes before the gases reach a process container, and inhibit a concentration gradient from occurring in the gases supplied into the process container.

According to one aspect of the present invention, there is provided a substrate processing apparatus configured to supply a first process gas and a second process gas into a process container accommodating a substrate, the apparatus including: a common pipe connected to the process container wherethrough the first process gas and the second process gas flow; a buffer unit connected to an upstream side of the common pipe and having a width greater than a diameter of the common pipe; a first supply pipe wherethrough the first process gas flows, wherein the first supply pipe is connected to one of a first surface of the buffer unit where the common pipe is connected and a second surface of the buffer unit opposite to the first surface; and a second supply pipe wherethrough the second process gas flows, wherein the second supply pipe is connected to one of the first surface and the second surface, wherein each of the first supply pipe and the second supply pipe is installed outer than the common pipe, and a distance between the first surface and the second surface is shorter than a distance between a center axis of the common pipe and a center axis of the first supply pipe and a distance between the center axis of the common pipe and a center axis of the second supply pipe.

According to another aspect of the present invention, there is provided a substrate processing apparatus configured to supply a first process gas and a second process gas into a process container accommodating a substrate, the apparatus including: a common pipe wherethrough the first process gas and the second process gas flow, connected to the process container; a buffer unit connected to an upstream side of the common pipe and having a width greater than a diameter of the common pipe; a first supply pipe wherethrough the first process gas flows, connected to a first surface of the buffer unit where the common pipe is connected or a second surface of the buffer unit opposite to the first surface; and a second supply pipe wherethrough the second process gas flows, connected to the first surface or the second surface of the buffer unit. In the apparatus, each of the first supply pipe and the second supply pipe is connected to the first surface or the second surface at a position outer than the common pipe, and a distance between the first surface and the second surface is equal to or shorter than twice a diameter of each of the first supply pipe and the second supply pipe.

According to another aspect of the present invention, there is provided a method of manufacturing a semiconductor device, including: processing a substrate by supplying a first process gas and a second process gas into a process container via a supply system including: a common pipe connected to the process container wherethrough the first process gas and the second process gas flow; a buffer unit connected to an upstream side of the common pipe and having a width greater than a diameter of the common pipe; a first supply pipe wherethrough the first process gas flows, wherein the first supply pipe is connected to one of a first surface of the buffer unit where the common pipe is connected and a second surface of the buffer unit opposite to the first surface; and a second supply pipe wherethrough the second process gas flows, wherein the second supply pipe is connected to one of the first surface and the second surface, wherein each of the first supply pipe and the second supply pipe is installed outer than the common pipe, and a distance between the first surface and the second surface is shorter than a distance between a center axis of the common pipe and a center axis of the first supply pipe and a distance between the center axis of the common pipe and a center axis of the second supply pipe.

According to another aspect of the present invention, there is provided a non-transitory computer-readable recording medium storing a program causing a computer to perform: processing a substrate by supplying a first process gas and a second process gas into a process container via a supply system including: a common pipe connected to the process container wherethrough the first process gas and the second process gas flow; a buffer unit connected to an upstream side of the common pipe and having a width greater than a diameter of the common pipe; a first supply pipe wherethrough the first process gas flows, wherein the first supply pipe is connected to one of a first surface of the buffer unit where the common pipe is connected and a second surface of the buffer unit opposite to the first surface; and a second supply pipe wherethrough the second process gas flows, wherein the second supply pipe is connected to one of the first surface and the second surface, wherein each of the first supply pipe and the second supply pipe is installed outer than the common pipe, and a distance between the first surface and the second surface is shorter than a distance between a center axis of the common pipe and a center axis of the first supply pipe and a distance between the center axis of the common pipe and a center axis of the second supply pipe.

### BRIEF DESCRIPTION OF THE DRAWINGS

FIG. 1 is a diagram of a substrate processing apparatus according to a first embodiment of the present invention.

FIG. 2 is a flowchart illustrating a substrate processing process of the substrate processing apparatus shown in FIG. 1.

FIG. 3 is a detailed flowchart illustrating a film forming process shown in FIG. 2.

FIG. 4 is a sequence diagram illustrating gas supply timing in the film forming process shown in FIG. 2.

FIG. 5 is a perspective view of the vicinity of a buffer unit shown in FIG. 1.

FIG. 6 is a cross-sectional view obtained by cutting the perspective view shown in FIG. 5 along a vertical surface passing through the center of each of a common pipe, a buffer unit, and supply pipes.

FIG. 7 is a plan view of a cut surface of the cross-sectional view shown in FIG. 6.

FIG. 8 is a perspective view of the vicinity of a buffer unit of a substrate processing apparatus according to a second embodiment of the present invention.

FIG. 9 is a perspective view of the vicinity of a substrate processing apparatus according to a third embodiment of the present invention.

FIG. 10 is a perspective view of the vicinity of a substrate processing apparatus according to a fourth embodiment of the present invention.

### DETAILED DESCRIPTION OF THE PREFERRED EMBODIMENTS

A first embodiment of the present invention will be now described with reference to the accompanying drawings below.

<Configuration of Apparatus>

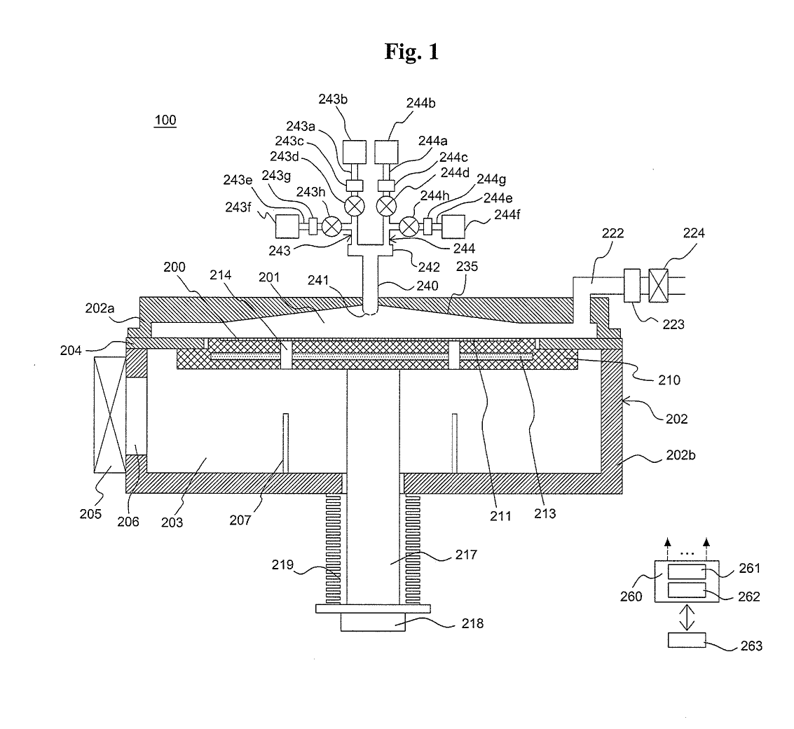

A configuration of a substrate processing apparatus 100 according to the present embodiment is illustrated in FIG. 1. The substrate processing apparatus 100 is configured as a single-wafer-type substrate processing apparatus as shown in FIG. 1.

(Process Container)

As shown in FIG. 1, the substrate processing apparatus 100 includes a process container 202. The process container 202 is configured as, for example, a planar airtight container having a circular cross-section. Also, the process container 202 is formed of a metal material, for example, aluminum (Al) or stainless steel (SUS). A process space 201 for processing a wafer (e.g., silicon wafer) which is a substrate and a transfer space 203 through which the wafer 200 passes when the wafer 200 is transferred to the process space 201 are formed in the process container 202. The process container 202 is configured using an upper container 202a and a lower container 202b. A partition plate 204 may be installed between the upper container 202a and the lower container 202b.

A substrate transfer port 206 is installed in a side surface of the lower container 202b and adjacent to a gate valve 205, and the wafer 200 is transferred between the process container 202 and a transfer chamber (not shown) via the substrate transfer port 206. A plurality of lift pins 207 are installed on a bottom portion of the lower container 202b.

A substrate support unit 210 for supporting the wafer 200 is installed in the process space 201. The substrate support unit 210 mainly includes a placing surface 211 for placing the wafer 200 and a heater 213 serving as a heating source. Through holes 214 through which the lift pins 207 are formed are respectively installed in positions corresponding to the lift pins 207.

The substrate support unit 210 is supported by a shaft 217. The shaft 217 penetrates a bottom portion of the process container 202 and is connected to an elevating mechanism 218 outside the process container 202. By moving the shaft 217 and the substrate support unit 210 upward/downward by operating the elevating mechanism 218, the wafer 200 loaded on the substrate placing surface 211 may be moved upward/downward. Also, the circumference of a lower end portion of the shaft 217 is coated with a bellows 219 to air-tightly maintain the inside of the process container 202.

The substrate support unit 210 is moved downward to a position in which the substrate placing surface 211 faces the substrate transfer port 206 (wafer transfer position) during the transfer of the wafer 200. During the processing of the wafer 200, the substrate support unit 210 is moved upward until the wafer 200 is in a process position of the process space 201 (wafer process position) as shown in FIG. 1.

Specifically, when the substrate support unit 210 is moved downward to the wafer transfer position, upper end portions of the lift pins 207 protrude from a top surface of the substrate placing surface 211 so that the lift pins 207 can support the wafer 200 from below. Also, when the substrate support unit 210 is moved upward to the wafer process position, the lift pins 207 are buried from the top surface of the substrate placing surface 211 so that the substrate placing surface 211 can support the wafer 200 from below. Also, since the lift pins 207 are in direct contact with the wafer 200, the lift pins 207 are preferably formed of a material such as quartz or alumina.

A gas supply system which will be described below is connected to an upper part of the process space 201 that is on the center axis of the wafer 200 [the substrate placing surface 211]. A ceiling surface 235 of the process space 201 has a cone shape whose apex is located at the center axis of the wafer 200 [the substrate placing surface 211].

(Gas Supply System)

A gas supply system includes at least a common pipe 240 through which a plurality of process gases pass, a dispersion plate 241 connected to the inside of a process space 201 and a downstream side of the common pipe 240, a buffer unit 242 connected to an upstream side of the common pipe 240, a first supply pipe 243 connected to the buffer unit 242, and a second supply pipe 244 connected to the buffer unit 242. Here, the plurality of process gases includes a first process gas and a second process gas having reactivity with respect to each other. In the present embodiment, the first process gas is titanium tetrachloride (TiCl₄), and the second process gas is ammonia (NH₃). TiCl₄ is supplied from the first supply pipe 243, and NH₃ is supplied from the second supply pipe 244.

The dispersion plate 241 has a hemispherical shape or a roughly hemispherical shape and an inner hollow portion. A plurality of pores or slits is installed in the dispersion plate 241. A gas supplied from the common pipe 240 into the dispersion plate 241 is dispersed by the pores or slits of the dispersion plate 241 and supplied to the entire process space 201. A shape of the buffer unit 242 will be described below.

The first supply pipe 243 includes a piping 243a, and a gas supply source 243b, a mass flow controller (MFC) 243c which is a flow rate control device (flow controller), and a valve 243d which is an opening/closing valve are sequentially installed at the piping 243a from an upstream end. The gas supply source 243b is a supply source of TiCl₄, and TiCl₄ gas which is adjusted to a predetermined flow rate by the MFC 243c is supplied to the buffer unit 242 by opening the valve 243d.

The first supply pipe 243 includes a piping 243e. The piping 243e is connected to the piping 243a at a downstream side of the valve 243d. A gas supply source 243f, an MFC 243g which is a flow rate control device (flow rate controller), and a valve 243h which is an opening/closing valve are sequentially installed at the piping 243e from the upstream end. The gas supply source 243f is a supply source of an inert gas, and an inert gas which is adjusted to a predetermined flow rate by the MFC 243g is supplied to the buffer unit 242 by opening the valve 243h. In the present embodiment, nitrogen (N₂) is used as the inert gas.

The second supply pipe 244 includes a piping 244a, and a gas supply source 244b, an MFC 244c which is a flow rate control device (flow rate controller), and a valve 244d which is an opening/closing valve 244d are sequentially installed at the piping 244a from the upstream end. The gas supply source 244b is a supply source of NH₃, and NH₃ gas which is adjusted to a predetermined flow rate by the MFC 244c is supplied to the buffer unit 242 by opening the valve 244d.

Furthermore, the second supply pipe 244 includes a piping 244e. The piping 244e is connected to the piping 244a at a downstream side of the valve 244d. A gas supply pipe 244f, an MFC 244g which is a flow rate control device (flow rate controller), and a valve 244h which is an opening/closing valve are sequentially installed at the piping 244e from the upstream side. The gas supply source 244f is a supply source of an inert gas, and an inert gas which is adjusted to a predetermined flow rate by the MFC 244g is supplied to the buffer unit 242 by opening the valve 244d. As the inert gas, not only N₂ gas but also a rare gas, such as helium (He) gas, neon (Ne) gas, argon (Ar) gas, etc., may be used.

(Gas Exhaust System)

A gas exhaust system for exhausting the atmosphere of the process container 202 [process space 201] includes an exhaust pipe 222 connected to the process container 202 [process space 201]. An auto pressure controller (APC) 223 which is a pressure controller and a valve 224 which is an opening/closing valve are sequentially installed at the exhaust pipe 222 from the upstream side. An exhaust pump (not shown) is connected to the exhaust pipe 222 further downstream.

The atmosphere of the process container 202 is exhausted using an exhaust pump by opening the valve 224. In this case, the inside of the process container 202 is controlled to a predetermined pressure by adjusting a conductance of the exhaust pipe 222 using the APC 223.

(Controller)

The substrate processing apparatus 100 includes a controller 260 configured to control an operation of each of components of the substrate processing apparatus 100. The controller 260 includes at least an operation unit 261 and a memory unit 262. The controller 260 is connected to each of the above-described components, calls a program or a recipe from the memory unit 262 in response to an instruction from the controller or a user, and controls the operation of each of the components according to the contents of the program or the recipe.

Further, the controller 260 may be constituted by an exclusive computer, and may also be constituted by a general-purpose computer. For example, an external memory device 263 (for example, a magnetic tape, a magnetic disk such as a flexible disk or a hard disk, an optical disc such as CD or DVD, a magneto-optical disc such as MO, a semiconductor memory such as a USB memory, a USB flash drive or a memory card), in which the program is stored, is prepared, and the program is installed on the general-purpose computer using the external memory device 263, so that the controller 260 according to the embodiment can be implemented.

In addition, means for supplying a program to a computer is not limited to the case in which the program is supplied via the external memory device 263. For example, the program may be supplied using communication means such as the Internet or an exclusive line, rather than via the external memory device 263. Further, the memory device 262 or the external memory device 263 is constituted by a recording medium readable by the computer. Hereinafter, these may be generally referred to as, simply, a recording medium. Furthermore, in the specification, cases in which the phrase “recording medium” is used may include cases in which the memory device 262 is solely included, cases in which the external memory device 263 is solely included, or cases in which both of them are included.

<Substrate Processing Process>

Next, a process of forming a thin film on the wafer 200 using the substrate processing apparatus 100 will be described. Also, in the following description, the operation of each of the components constituting the substrate processing apparatus 100 is controlled by the controller 260.

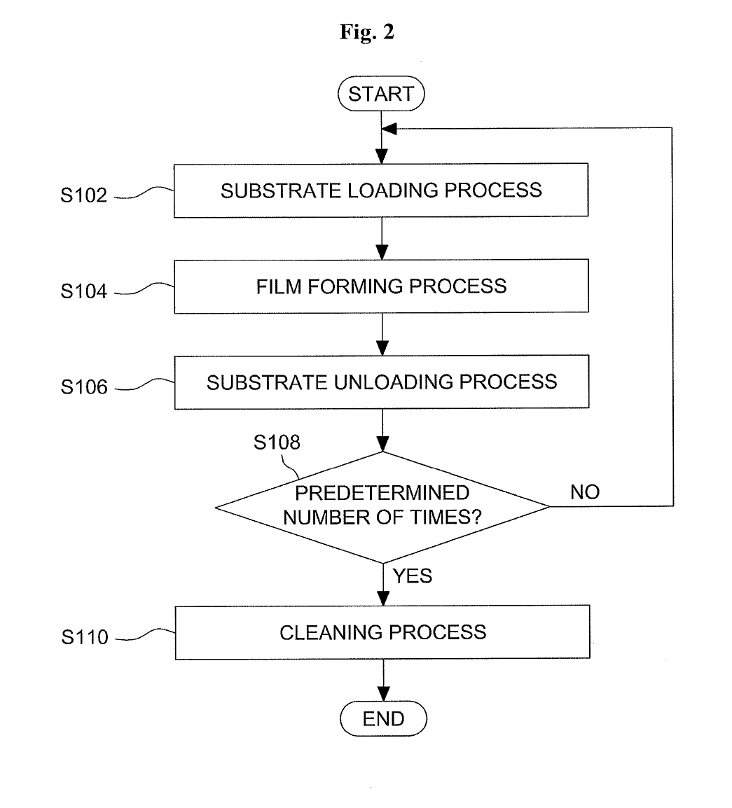

FIG. 2 is a flowchart illustrating a substrate processing process according to the present embodiment.

Hereinafter, an example in which a titanium nitride (TiN) film is formed using TiCl₄ supplied from the first supply pipe 243 and NH₃ supplied from the second supply pipe 244 will be described.

(Substrate Loading Process S102)

To begin with, the lift pins 207 are formed through the through holes 214 of the substrate support unit 210 by moving the substrate support unit 210 to a transfer position of the wafer 200. As a result, the lift pins 207 protrude only as much as a predetermined height from the substrate placing surface 211. Subsequently, the gate valve 205 is opened to cause the transfer space 203 to communicate with a carrying chamber (not shown). Also, the wafer 200 is loaded from the carrying chamber into the transfer space 203 using a wafer carrier (not shown), and carried onto the lift pins 207. Thus, the wafer 200 is supported on the lift pins 207 in a horizontal posture.

When the wafer 200 is loaded into the process container 202, the wafer carrier is taken out from the process container 202, and the gate valve 205 is closed to air-tightly close the inside of the process container 202. Thereafter, the wafer 200 is placed on the substrate placing surface 211 of the substrate support unit 210 by moving the substrate support unit 210 upward. Also, the wafer 200 is moved upward to the above-described position of the process space 201 by moving the substrate support unit 210 upward.

(Film Forming Process S104)

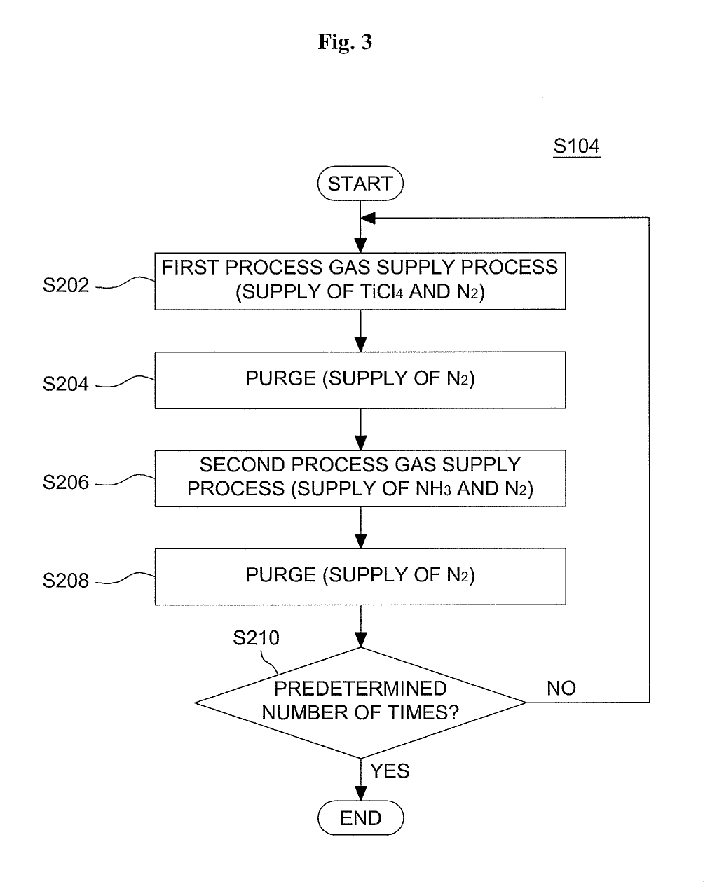

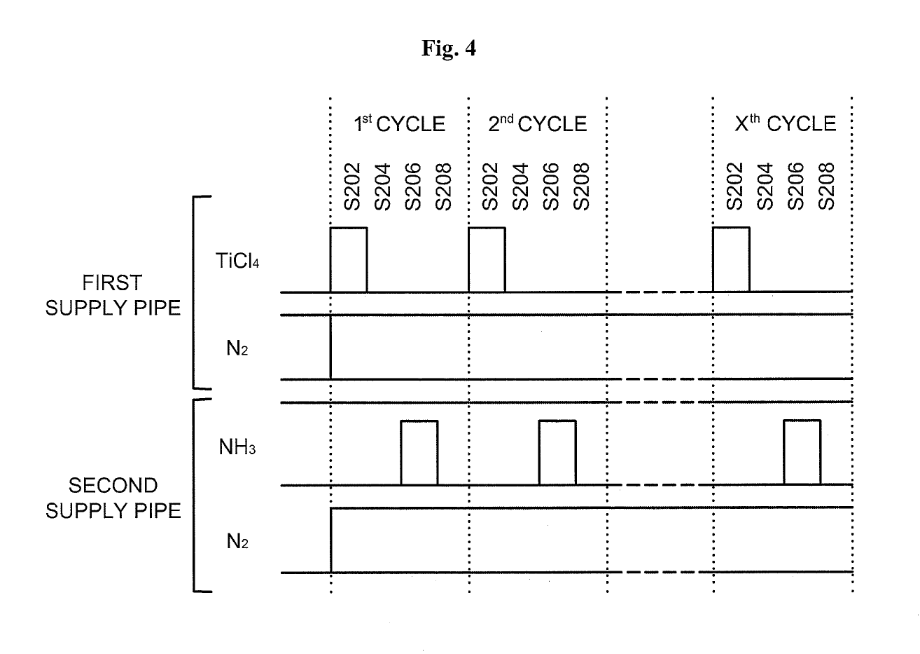

Next, a thin film forming process S104 is performed. FIG. 3 is a detailed flowchart illustrating the film forming process S104 of FIG. 2. FIG. 4 is a sequence diagram illustrating gas supply timings in the film forming process S104 of FIG. 2. Hereinafter, the film forming process S104 will be described in detail with reference to FIGS. 3 and 4. Also, the film forming process S104 is a cycling process including repeating a process of alternately supplying different process gases (TiCl₄ and NH₃).

(First Process Gas Supply Process S202)

When the wafer 200 is heated and reaches a desired temperature, the MFC 243c is adjusted by opening the valve 243d of the first supply pipe 243 so that TiCl₄ gas having a predetermined flow rate can be supplied from the first supply pipe 243. The flow rate of TiCl₄ gas supplied from the first supply pipe 243 is set to be in the range of, for example, 100 to 3,000 sccm, preferably 500 to 2,000 sccm.

Further, the above flow rate may be directly controlled by the MFC 243c. Alternatively, a tank for storing gas may be installed between the MFC 243c and the valve 243d, and the above flow rate may be a flow rate of the gas flowing out of the tank. In both cases, a high flow rate can be supplied within a short time (for example, shorter than 0.1 sec).

In the present embodiment, the flow rate of TiCl₄ gas supplied from the first supply pipe 243 is set to be 1,000 sccm. By supplying the TiCl₄ gas, a titanium-containing layer is formed on the wafer 200 to a thickness of less than one atomic layer to several atomic layers.

In this case, the MFC 243g is adjusted by opening the valve 243h of the first supply pipe 243 so that N₂ gas having a predetermined flow rate can be supplied from the first supply pipe 243 along with TiCl₄ gas. The flow rate of N₂ gas supplied from the first supply pipe 243 is set to be in the range of, for example, 1,000 to 2,000 sccm. In the present embodiment, the flow rate of N₂ gas supplied from the first supply pipe 243 is set to be 1,500 sccm. Also, the MFC 244g is adjusted by opening the valve 244h of the second supply pipe 244 so that N₂ gas having a predetermined flow rate can be supplied from the second supply pipe 244. Similar to the flow rate of N₂ gas supplied from the first supply pipe 243, the flow rate of N₂ gas supplied from the second supply pipe 244 is set to be in the range of, for example, 1,000 to 2,000 sccm. In the present embodiment, the flow rate of N₂ gas supplied from the second supply pipe 244 is set to be 1,500 sccm. Also, the supply of N₂ gas from each of the supply pipes 243 and 244 may start before the first process gas supply process S202.

After a predetermined time has elapsed since the supply of TiCl₄ gas started, the supply of TiCl₄ gas is stopped by closing the valve 243d. Meanwhile, the valve 243h and the valve 244h remain opened.

(Purge Process S204)

In a purge process S204, N₂ gas is supplied from the first supply pipe 243 and the second supply pipe 244 via the valve 243h and the valve 244h which remain opened, so that TiCl₄ gas remaining in the process container 202 can be exhausted from the process container 202. In this case, the flow rate of N₂ gas is set to be, for example, 1,500 sccm.

(Second Process Gas Supply Process S206)

Thereafter, the MFC 244c is adjusted by opening the valve 244d of the second supply pipe 244 so that NH₃ gas having a predetermined flow rate can be supplied from the second supply pipe 244. The flow rate of NH₃ gas supplied from the second supply pipe 244 is set to be in the range of, for example, 2,000 to 7,000 sccm, preferably 3,000 to 6,000 sccm.

Further, the above flow rate may be directly controlled by the MFC 244c. Alternatively, a tank for storing gas may be installed between the MFC 244c and the valve 244d, and the above flow rate may be a flow rate of the gas flowing out of the tank. In both cases, a high flow rate can be supplied within a short time (for example, shorter than 0.5 sec).

In the present embodiment, the flow rate of NH₃ gas supplied from the second supply pipe 244 is set to be 5,000 sccm. The supplied NH₃ gas reacts with at least a portion of the titanium-containing layer formed on the wafer 200. Thus, the titanium-containing layer is nitrided to form a titanium nitride (TiN) layer.

In the process S206, the valve 243h of the first supply pipe 243 and the valve 244h of the second supply pipe 244 are opened to supply N₂ gas having a flow rate of, for example, 1,500 sccm from each of the first supply pipe 243 and the second supply pipe 244.

After a predetermined time has elapsed since the supply of NH₃ gas started, the valve 244d is closed to stop the supply of NH₃ gas. Similarly, the valve 243h and the valve 244h remain opened.

(Purge Process S208)

In a purge process S208, similar to the process S204, N₂ gas is supplied from the first supply pipe 243 and the second supply pipe 244 via the valve 243h and the valve 244h which remain opened, so that NH₃ gas remaining in the process container 202 can be exhausted from the process container 202. In this case, the flow rate of N₂ gas is set to be, for example, 1,500 sccm.

(Cycle Number Determining Process S210)

Thereafter, the controller 260 determines whether or not the one cycle has been performed a predetermined number of times (X cycles). When the one cycle has not been performed the predetermined number of times (in the case of No in step S210), a cycle including the first process gas supply process S202, the purge process S204, the second process gas supply process S206, and the purge process S208 is repeated. When the one cycle has been performed the predetermined number of times (in the case of Yes in step S210), a processing process shown in FIG. 3 ends.

In the present embodiment, N₂ gas having a predetermined flow rate is continuously supplied from both the first supply pipe 243 and the second supply pipe 244 in the film forming process S104. Thus, since unnecessary process gases (TiCl₄ and NH₃) which have not contributed to the formation of a film are rapidly exhausted from the process container 202, a purge time may be reduced (or may not be needed) to improve the throughput.

Referring back to the description of FIG. 2, a substrate unloading process S106 is performed.

(Substrate Unloading Process S106)

In a substrate unloading process S106, the substrate support unit 210 is moved downward to support the wafer 200 on the lift pins 207 protruding from the surface of the substrate placing surface 211. Thus, the wafer 200 is moved from the process position to the transfer position. Thereafter, the gate valve 205 is opened to unload the wafer 200 from the process container 202 using the wafer carrier.

(Process Number Determining Process S108)

After the wafer 200 is unloaded, it is determined whether or not the number of times the film forming process was performed has reached a predetermined number of times. When it is determined that the number of times the film forming process was performed has reached the predetermined number of times, the substrate processing process enters a cleaning process. When it is determined that the number of times the film forming process was performed has not reached the predetermined number of times, the substrate processing process enters a substrate loading/placing process S102 to start processing the next wafer 200 which is on standby.

(Cleaning Process S110)

When it is determined that the number of times the film forming process was performed has reached the predetermined number of times in the process number determining process S108, the cleaning process is performed. In the cleaning process, byproducts attached to walls of the process container 202 are removed using a cleaning gas. Although not shown, a cleaning gas supply source may be connected to the first supply pipe 243 or the second supply pipe 244 and a cleaning gas used in the cleaning process may be supplied from the cleaning gas supply source, or another supply system may be additionally installed.

As described above, in the present embodiment, N₂ gas having a predetermined flow rate is continuously supplied from both the first supply pipe 243 and the second supply pipe 244 in the film forming process S104. The N₂ gas supplied from each of the supply pipes 243 and 244 is supplied into the process container 202 via the common pipe 240 together with the process gases (TiCl₄ and NH₃) supplied from one of the supply pipes 243 and 244. Thus, a concentration gradient is preferably inhibited from occurring in the gas supplied into the process container 202 by uniformly mixing the gases supplied from the respective supply pipes 243 and 244.

Thus, the substrate processing apparatus 100 according to the present embodiment was configured such that the buffer unit 242 is installed at an upstream side of the common pipe 240 and mixes the gases supplied from the respective supply pipes 243 and 244.

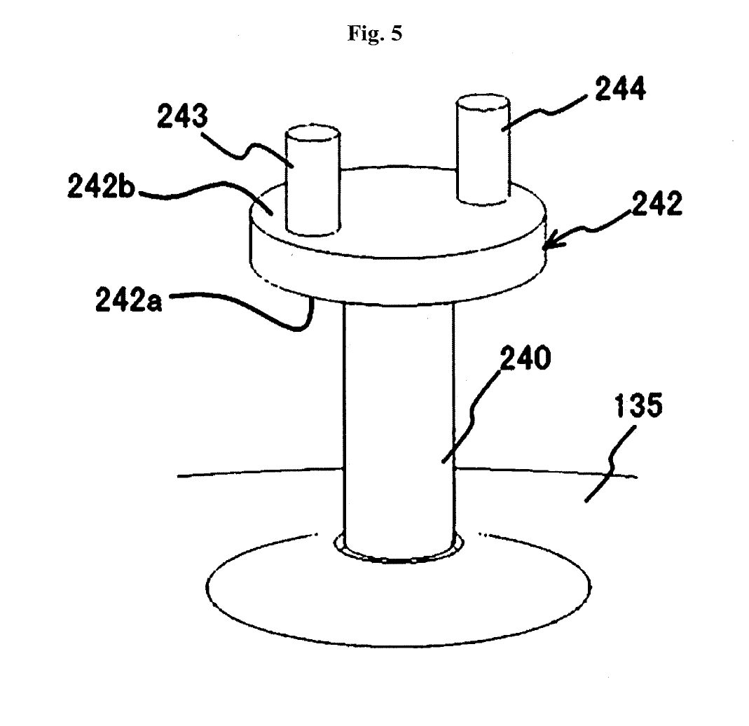

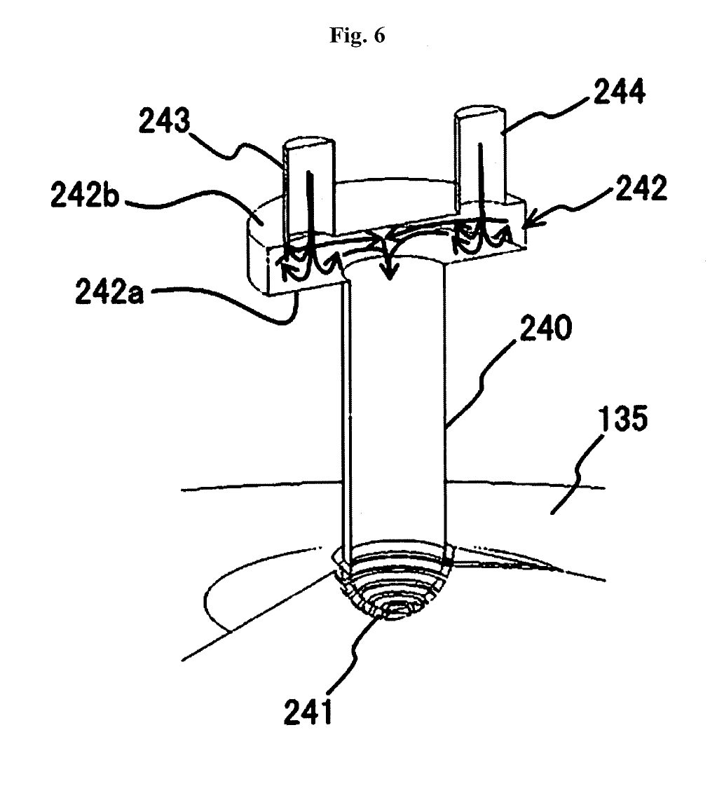

FIG. 5 is a perspective view of the vicinity of the buffer unit 242. FIG. 6 is a cross-sectional view obtained by cutting the perspective view shown in FIG. 5 along a vertical surface passing through the center of each of the common pipe 240, the buffer unit 242, and the supply pipes 243 and 244. As shown in FIGS. 5 and 6, the buffer unit 242 has a cylindrical shape having a greater width than a diameter of the common pipe 240.

The common pipe 240 is connected to the center of a bottom surface 242a (first surface) of the buffer unit 242. Also, the first supply pipe 243 and the second supply pipe 244 are connected to a top surface 242b (second surface disposed opposite to the first surface) of the buffer unit 242. The supply pipes 243 and 244 are symmetrically disposed via the common pipe 240 [specifically, via an extension line of the common pipe 240]. Also, the first supply pipe 243 and the second supply pipe 244 are connected to the buffer unit 242 at an inner side from a peripheral edge portion of the top surface 242b of the buffer unit 242.

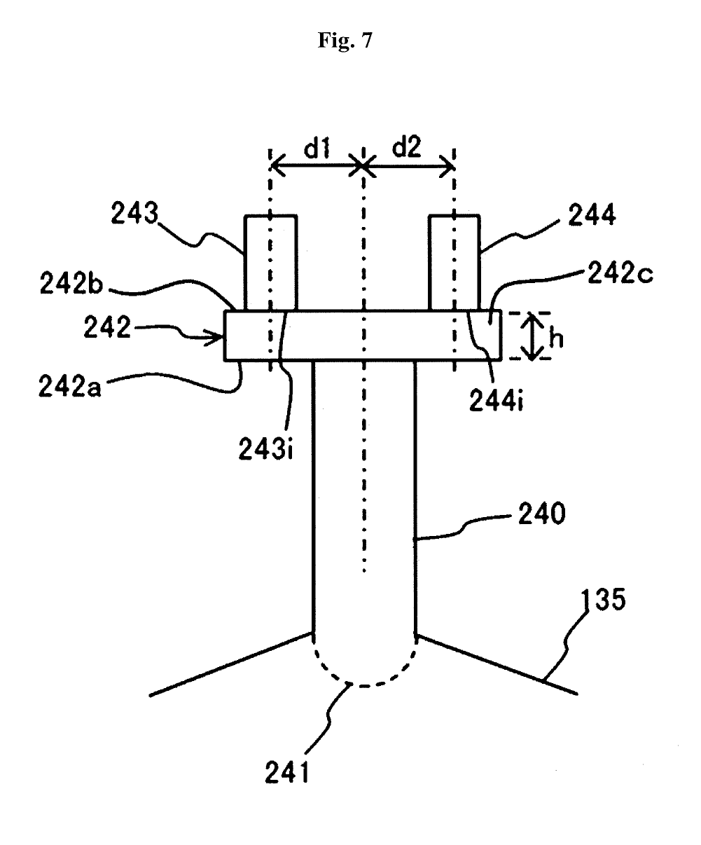

FIG. 7 is a plan view of a cut surface of the cross-sectional view shown in FIG. 6. As shown in FIG. 7, the first supply pipe 243 and the second supply pipe 244 are connected to the top surface 242b of the buffer unit 242 at an outer circumferential side from the common pipe 240. Thus, an inner circumferential wall surface [bottom surface] 242a of the buffer unit 242 is installed opposite to gas supply ports 243i and 244i of the respective supply pipes 243 and 244.

Thereafter, dimensions of respective components will be described. As shown in FIG. 7, the buffer unit 242 is formed such that a height h of the buffer unit 242 [a distance between the bottom surface 242a and the top surface 242b, more specifically, a distance between an inner wall bottom surface and an inner wall top surface] becomes a distance d1 between a central line of the common pipe 240 and a central line of the first supply pipe 243 and a distance d2 between the central line of the common pipe 240 and a central line of the second supply pipe 244.

Examples of specific dimensions will now be presented. Each of a diameter (inner diameter) φ₁ of the first supply pipe 243 and a diameter (inner diameter) φ₂ of the second supply pipe 244 is 11 mm, a diameter (inner diameter) φc of the common pipe 240 is 22 mm, and a diameter φb of the buffer unit 242 is 60 mm. Also, the common pipe 240 has a height [a distance from the buffer unit 242 to the dispersion plate 241] of 60 mm, and the buffer unit 242 has a height h of 10 mm. Also, a distance of the central line of the first supply pipe 243 to the central line of the second supply pipe 244 is 40 mm. Accordingly, each of the above-described distances d1 and d2 is 20 mm, and the height h of the buffer unit 242 is less than 20 mm. Also, a space [denoted by 242c in FIG. 7] having a width of about 5 mm is formed between each of the supply pipes 243 and 244 and the peripheral edge portion of the buffer unit 242.

Thus, the first supply pipe 243 and the second supply pipe 244 are connected to the buffer unit 242 at an outer circumferential side from the common pipe 240, and the buffer unit 242 is formed such that the height h of the buffer unit 242 is less than the distance d1 between the central line of the common pipe 240 and the central line of the first supply pipe 243 and the distance d2 between the central line of the common pipe 240 and the central line of the second supply pipe 244. Thus, as indicated by arrows in FIG. 6, before the gases supplied from the first supply pipe 243 and the second supply pipe 244 naturally diffuse into the buffer unit 242, the gases easily collide with the inner circumferential wall surface [surface disposed opposite the gas supply ports 243i and 244i of the respective supply pipes 243 and 244] of the buffer unit 242 and are dispersed effectively and rapidly in the buffer unit 242 to promote the mixing of the gases. Thus, the gases supplied from the respective supply pipes 243 and 244 are mixed before the gases reach the process container 202 so that a concentration gradient can be inhibited from occurring in the gases supplied into the process container 202.

Specifically, in the film forming process according to the present embodiment, a period (when supplying TiCl₄, the total flow rate of the TiCl₄ gas and the N₂ gas supplied from the first supply pipe 243 is 2500 sccm, but the total flow rate of the N₂ gas supplied from the second supply pipe 244 1500 sccm) when the flow rate of gas supplied via the first supply pipe 243 is higher than that of gas supplied via the second supply pipe 244 and a period (when supplying NH₃, the total flow rate of the N₂ gas supplied from the first supply pipe 243 is 1500 sccm, but the total flow rate of the NH₃ gas and the N₂ gas supplied from the second supply pipe 244 is 6500 sccm) when the flow rate of gas supplied via the first supply pipe 243 is lower than that of gas supplied via the second supply pipe 244 are switched between each other. However, in any case, since the gases supplied from the respective supply pipes 243 and 244 collide with the inner circumferential wall surface of the buffer unit 242 and then are dispersed in the buffer unit 242, the mixing of the gases is not easily affected by the forced switching of the flow rates of the gases supplied from the respective supply pipes 243 and 244. Thus, the gases may be uniformly mixed.

By deliberately setting the height of the buffer unit 242 to cause the gases supplied from the supply pipes 243 and 244 to collide with the inner circumferential wall surface of the buffer unit 242, the height (thickness) of the buffer unit 242 may be inhibited and miniaturized. For example, rotation of the gases in the common pipe 240 is inhibited as compared with a case in which each of the gas supply pipes 243 and 244 is connected to a side surface of the common pipe 240. Thus, gases passing through the common pipe 240 may be expected to be uniformly supplied by the wafer 200.

In addition, the first supply pipe 243 and the second supply pipe 244 are connected to the buffer unit 242 at an inner side from the peripheral edge portion of the buffer unit 242. In other words, since the space 242c is formed between each of the supply pipes 243 and 244 and the peripheral edge portion of the buffer unit 242, gases which have collided with the inner circumferential wall surface of the buffer unit 242 are dispersed in the buffer unit 242 more effectively (in more directions) to further promote the mixing of the gases.

As described above, the buffer unit 242 is preferably formed such that the height h of the buffer unit 242 is less than the distance d1 between the central line of the common pipe 240 and the central line of the first supply pipe 243 and the distance d2 of the central line of the second supply pipe 244. However, from a different viewpoint, similar effects may also be expected by determining the height h of the buffer unit 242. For example, by setting the height h of the buffer unit 242 to be equal or approximately equal to each of the diameters φ₁ and φ₂ of the supply pipes 243 and 244 or to be no more than twice the diameters φ₁ and φ₂ of the supply pipes 243 and 244, the gases supplied from the respective pipes 243 and 244 may be expected to collide with the inner circumferential wall surface of the buffer unit 242 and be dispersed before the speed of the gases is reduced.

As described above, the gases easily collide with the inner circumferential wall surface of the buffer unit 242 to be dispersed by supplying the gas from each of the gas supply pipes 243 and 244 in a high flow rate (for example, 1000 sccm or higher) within a short time. Therefore, mixing of the gases can be facilitated, and the processing time of the wafer 200 can be reduced.

A case in which the buffer unit 242 and each of the supply pipes 243 and 244 are connected to the common pipe 240 in a vertical direction has been described above. However, for example, the common pipe 240 may be bent at an angle of 90° to be connected the buffer unit 242 and each of the supply pipes 243 and 244 in a horizontal direction. Also, although a case in which the buffer unit 242 has the cylindrical shape has been described above, the buffer unit 242 may have a different shape as long as the buffer unit 242 has a greater width than the common pipe 240. For example, from a plan view, the buffer unit 242 may have a square pillar shape or an elliptical pillar shape. When the buffer unit 242 has an elliptical shape from a plan view, a short side of the elliptical shape of the buffer unit 242 is set to be equal to or greater than the diameter of the common pipe 240. Also, although the space 242c is formed by connecting the first supply pipe 243 and the second supply pipe 244 to the buffer unit 242 at an inner side from the peripheral edge portion of the buffer unit 242, each of the supply pipes 243 and 244 may be in contact with the peripheral edge portion of the buffer unit 242 and the space 242c may not be formed.

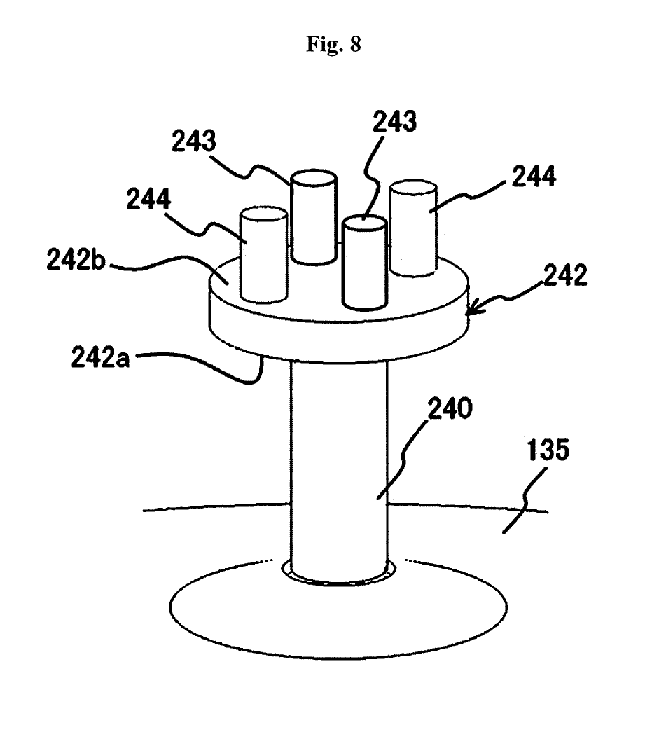

Next, the substrate processing apparatus according to a second embodiment of the present invention will be described. FIG. 8 is a perspective view of the vicinity of the buffer unit 242 of the substrate processing apparatus according to the second embodiment. The substrate processing apparatus according to the second embodiment includes pluralities of the first supply pipes 243 and second supply pipes 244 described above (two first supply pipes 243 and two second supply pipes 244 are illustrated in the example of FIG. 8). The first supply pipes 243 and the second supply pipes 244 are alternately connected to the top surface 242b of the buffer unit 242 on a concentric circle having the common pipe 240 (specifically, an extension line of the common pipe 240) as a center. Specifically, the four supply pipes 243 and 244, i.e., the first supply pipes 243 and the second supply pipes 244, are alternately disposed at intervals of 90° on the concentric circle having the common pipe 240 as the center. Each of the supply pipes 243 and 244 is connected to the top surface 242b of the buffer unit 242 at an outer circumferential side from the common pipe 240 and at an inner side from the peripheral edge portion of the top surface 242b of the buffer unit 242. A flow rate of a gas flowing through each of the supply pipes 243 and 244 is set to be, for example, ½ the example presented in the first embodiment. Also, since other components are the same as in the first embodiment, a description thereof will be omitted.

In the second embodiment, the substrate processing apparatus includes a plurality of first supply pipes 243 and a plurality of second supply pipes 244 and is configured such that the respective supply pipes 243 and 244 are alternately connected to the top surface 242b of the buffer unit 242 on a concentric circle having the common pipe 240 as a center. Thus, gases supplied from the respective supply pipes 243 and 244 may be mixed more uniformly.

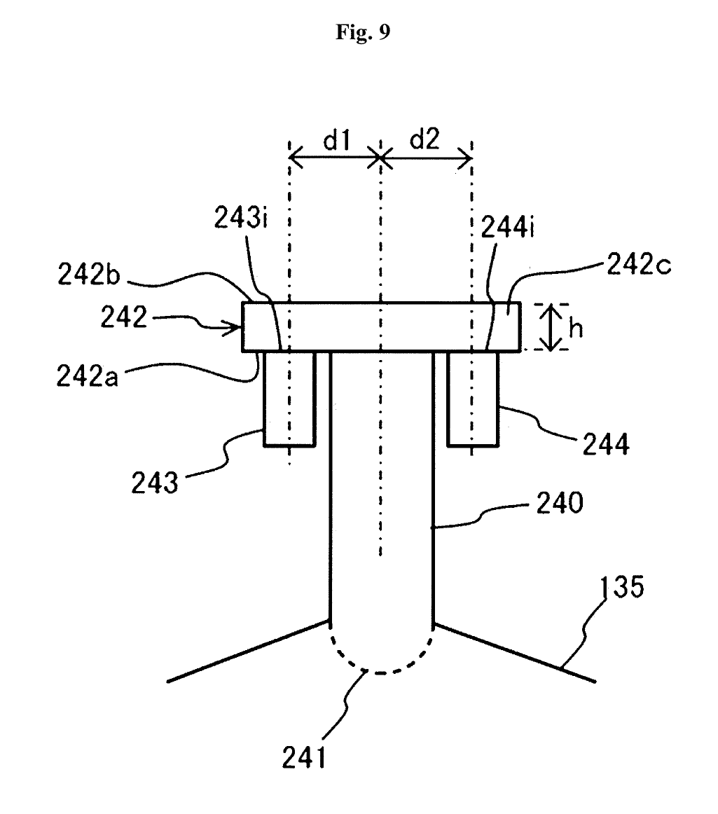

Next, a substrate processing apparatus according to a third embodiment of the present invention will be described. FIG. 9 is a perspective view of the vicinity of a buffer unit 242 of the substrate processing apparatus according to the third embodiment. The substrate processing apparatus according to the third embodiment is configured such that a first supply pipe 243 and a second supply pipe 244 are connected to a bottom surface 242a of the buffer unit 242. That is, in the present embodiment, the first supply pipe 243 and the second supply pipe 244 are connected to a surface of the buffer unit 242 to which the common pipe 240 is connected. Also, since other components are the same as in the first embodiment, a description thereof will be omitted. In the present embodiment, a plurality of first supply pipes 243 and a plurality of second supply pipes 244 may be installed similar to the second embodiment.

In the third embodiment, by connecting the first supply pipe 243 and the second supply pipe 244 to the surface of the buffer unit 242 to which the common pipe 240 is connected, a direction in which the gases supplied from the supply pipes 243 and 244 flow is switched to the opposite direction in the buffer unit 242 so that the gases can be effectively mixed when switching the directions of gas flow. Also, since the length of the gas supply system may be inhibited from increasing in a flow-path direction of the common pipe 240, the length of the common pipe 240 may be ensured to be the same as, for example, when each gas supply pipe is connected to a side surface of the common pipe 240, and gases may be sufficiently mixed in the common pipe 240.

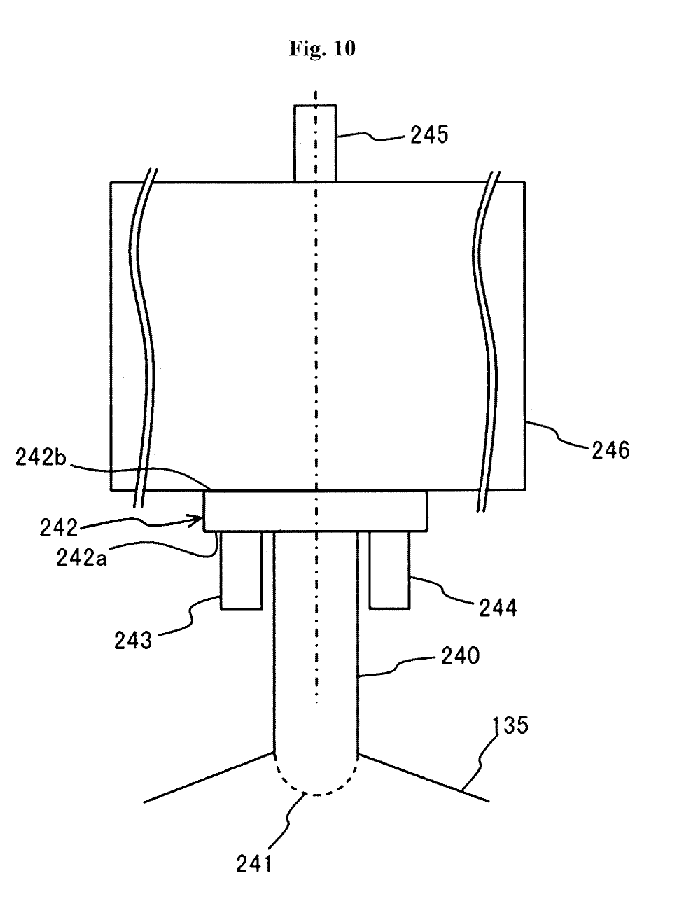

Next, a substrate processing apparatus according to a fourth embodiment of the present invention will be described. FIG. 10 is a perspective view of the vicinity of a buffer unit 242 of the substrate processing apparatus according to the fourth embodiment. In the fourth embodiment, a third supply pipe 245 is added to the supply system according to the third embodiment. The third supply pipe 245 is connected to a top surface 242b of the buffer unit 242 via a remote plasma unit (RPU) 246 which is a plasma generating unit. That is, the RPU 246 is installed between the buffer unit 242 and the third supply pipe 245. Here, the common pipe 240, the RPU 246, and the third supply pipe 245 are disposed on the same axial line.

A gas supply source (not shown), an MFC (not shown), and a valve (not shown) are installed at an upstream side of the third supply pipe 245. A gas supplied from the third supply pipe 245 is processed using the RPU 246 and generates plasma, and the plasma is supplied into the process container 202 via the buffer unit 242 and the common pipe 240. Since other components are the same as in the third embodiment, a description thereof will be omitted.

A cleaning gas, for example, nitrogen trifluoride (NF₃), etc., may be supplied from the third supply pipe 245. Also, when an oxide film is formed, an oxidizing agent, such as oxygen, etc., may be supplied from the third supply pipe 245. When a nitride film is formed, a nitriding agent, such as nitrogen, etc., may be supplied from the third supply pipe 245. Here, the gas supplied from the third supply pipe 245 is preferably a gas (a gas having a different supply timing) which does not need to be mixed with the process gases supplied from the first supply pipe 243 and the second supply pipe 244.

In general, plasma is easily deactivated. However, in the fourth embodiment, since the common pipe 240, the RPU 246, and the third supply pipe 245 are disposed on the same axial line and the RPU 246 is disposed directly on the buffer unit 242, in addition to the effects according to the third embodiment, the plasma generated from the gases may be rapidly supplied into the process container 202 before the plasma is deactivated.

While a film forming technique according to various typical embodiments of the present invention has been described, the present invention is not limited thereto. For example, the present invention may be applied to not only formation of films other than the thin films described above but also other substrate processing processes, such as a diffusion process, an oxidation process, a nitridation process, a lithography process, etc. Also, the present invention may be applied to not only an annealing processing apparatus but also another substrate processing apparatus, such as a thin film forming apparatus, an etching apparatus, an oxidation apparatus, a nitridation apparatus, a coating apparatus, a heating apparatus, etc. Also, the present invention may be applied to a mixture of the above-described apparatuses. Furthermore, some components according to one embodiment may be replaced with components according to another embodiment, and components according to one embodiment may be added to components according to another embodiment. Also, other components may be added to, deleted from, or replaced with some components according to each embodiment.

According to the present invention, gases supplied from a plurality of supply pipes can be mixed before the gases reach a process container, so that a concentration gradient can be inhibited from occurring in the gases supplied into the process container.

(Preferred Mode of the Present Invention)

Embodiments of the present invention will be supplementarily described below.

(Supplementary Note 1)

According to one aspect of the present invention, there is provided a substrate processing apparatus configured to supply a first process gas and a second process gas into a process container accommodating a substrate, the apparatus including: a common pipe connected to the process container wherethrough the first process gas and the second process gas flow; a buffer unit connected to an upstream side of the common pipe and having a width greater than a diameter of the common pipe; a first supply pipe wherethrough the first process gas flows, wherein the first supply pipe is connected to one of a first surface of the buffer unit where the common pipe is connected and a second surface of the buffer unit opposite to the first surface; and a second supply pipe wherethrough the second process gas flows, wherein the second supply pipe is connected to one of the first surface and the second surface, wherein each of the first supply pipe and the second supply pipe is installed outer than the common pipe, and a distance between the first surface and the second surface is shorter than a distance between a center axis of the common pipe and a center axis of the first supply pipe and a distance between the center axis of the common pipe and a center axis of the second supply pipe.

(Supplementary Note 2)

The apparatus of Supplementary note 1, wherein the first supply pipe and the second supply pipe are connected to the first surface.

(Supplementary Note 3)

The apparatus of Supplementary note 1 or Supplementary note 2, wherein an inert gas is continuously supplied via each of the first supply pipe and the second supply pipe, and the first process gas and the second process gas are alternately supplied via the first supply pipe and the second supply pipe.

(Supplementary Note 4)

The apparatus of any one of Supplementary notes 1 through 3, wherein each of the first supply pipe and the second supply pipe includes a plurality of supply pipes, and the plurality of supply pipes of the first supply pipe and the plurality of supply pipes of the second supply pipe are alternately and circumferentially disposed on one of the first surface and the second surface, a center of the circle located in the common pipe.

(Supplementary Note 5)

The apparatus of any one of Supplementary notes 1 through 4, wherein at least one of the first supply pipe and the second supply pipe is disposed inner than a peripheral portion of one of the first surface and the second surface.

(Supplementary Note 6)

The apparatus of any one of Supplementary notes 1 through 5 may further include a third supply pipe connected to the second surface, and the common pipe and the third supply pipe are disposed on a same axis.

(Supplementary Note 7)

The apparatus of Supplementary note 6 may further include a plasma generator installed between the buffer unit and the third supply pipe.

(Supplementary Note 8)

According to another aspect of the present invention, there is provided a substrate processing apparatus configured to supply a first process gas and a second process gas into a process container accommodating a substrate, the apparatus including: a common pipe connected to the process container wherethrough the first process gas and the second process gas flow; a buffer unit connected to an upstream side of the common pipe and having a width greater than a diameter of the common pipe; a first supply pipe wherethrough the first process gas flows, connected to a first surface of the buffer unit where the common pipe is connected or a second surface of the buffer unit opposite to the first surface; and a second supply pipe wherethrough the second process gas flows, connected to the first surface or the second surface. In the apparatus, each of the first supply pipe and the second supply pipe is connected to the first surface or the second surface at a position outer than the common pipe, and a distance between the first surface and the second surface of the buffer unit is equal to or shorter than twice a diameter of each of the first supply pipe and the second supply pipe.

(Supplementary Note 9)

According to another aspect of the present invention, there is provided a method of manufacturing a semiconductor device, including: processing a substrate by supplying a first process gas and a second process gas into a process container via a supply system including: a common pipe wherethrough the first process gas and the second process gas flow, connected to the process container; a buffer unit connected to an upstream side of the common pipe and having a width greater than a diameter of the common pipe; a first supply pipe wherethrough the first process gas flows, wherein the first supply pipe is connected to one of a first surface of the buffer unit where the common pipe is connected and a second surface of the buffer unit opposite to the first surface; and a second supply pipe wherethrough the second process gas flows, wherein the second supply pipe is connected to one of the first surface and the second surface, wherein each of the first supply pipe and the second supply pipe is installed outer than the common pipe, and a distance between the first surface and the second surface is shorter than a distance between a center axis of the common pipe and a center axis of the first supply pipe and a distance between the center axis of the common pipe and a center axis of the second supply pipe.

(Supplementary Note 10)

According to another aspect of the present invention, there is provided a program causing a computer to perform: processing a substrate by supplying a first process gas and a second process gas into a process container via a supply system including: a common pipe connected to the process container wherethrough the first process gas and the second process gas flow; a buffer unit connected to an upstream side of the common pipe and having a width greater than a diameter of the common pipe; a first supply pipe wherethrough the first process gas flows, wherein the first supply pipe is connected to one of a first surface of the buffer unit where the common pipe is connected and a second surface of the buffer unit opposite to the first surface; and a second supply pipe wherethrough the second process gas flows, wherein the second supply pipe is connected to one of the first surface and the second surface, wherein each of the first supply pipe and the second supply pipe is installed outer than the common pipe, and a distance between the first surface and the second surface is shorter than a distance between a center axis of the common pipe and a center axis of the first supply pipe and a distance between the center axis of the common pipe and a center axis of the second supply pipe.

(Supplementary Note 11)

According to another aspect of the present invention, there is provided a non-transitory computer-readable recording medium storing a program causing a computer to perform: processing a substrate by supplying a first process gas and a second process gas into a process container via a supply system including: a common pipe connected to the process container wherethrough the first process gas and the second process gas flow; a buffer unit connected to an upstream side of the common pipe and having a width greater than a diameter of the common pipe; a first supply pipe wherethrough the first process gas flows, wherein the first supply pipe is connected to one of a first surface of the buffer unit where the common pipe is connected and a second surface of the buffer unit opposite to the first surface; and a second supply pipe wherethrough the second process gas flows, wherein the second supply pipe is connected to one of the first surface and the second surface, wherein each of the first supply pipe and the second supply pipe is installed outer than the common pipe, and a distance between the first surface and the second surface is shorter than a distance between a center axis of the common pipe and a center axis of the first supply pipe and a distance between the center axis of the common pipe and a center axis of the second supply pipe.

What is claimed is:

1. A substrate processing apparatus configured to supply a first process gas and a second process gas into a process container accommodating a substrate, the apparatus comprising:
a common pipe connected to the process container wherethrough the first process gas and the second process gas flow;
a buffer unit connected to an upstream side of the common pipe and having a width greater than a diameter of the common pipe;
a first supply pipe wherethrough the first process gas flows, wherein the first supply pipe is connected to one of a first surface of the buffer unit where the common pipe is connected and a second surface of the buffer unit opposite to the first surface; and
a second supply pipe wherethrough the second process gas flows, wherein the second supply pipe is connected to one of the first surface and the second surface,
wherein each of the first supply pipe and the second supply pipe is installed outer than the common pipe, and
a distance between the first surface and the second surface is shorter than a distance between a center axis of the common pipe and a center axis of the first supply pipe and a distance between the center axis of the common pipe and a center axis of the second supply pipe.

2. The apparatus of claim 1, wherein the first supply pipe and the second supply pipe are connected to the first surface.

3. The apparatus of claim 1, wherein an inert gas is continuously supplied via each of the first supply pipe and the second supply pipe, and the first process gas and the second process gas are alternately supplied via the first supply pipe and the second supply pipe.

4. The apparatus of claim 3, wherein an inequality between a total flow rate of the inert gas and the first process gas supplied via the first supply pipe and that of the inert gas and the second process gas supplied via the second supply pipe is changed while the substrate is processed.

5. The apparatus of claim 3, wherein each of the total flow rate of the inert gas and the first process gas supplied via the first supply pipe and that of the inert gas and the second process gas supplied via the second supply pipe is equal to or greater than 1,000 sccm.

6. The apparatus of claim 1, wherein each of the first supply pipe and the second supply pipe includes a plurality of supply pipes, and
the plurality of supply pipes of the first supply pipe and the plurality of supply pipes of the second supply pipe are alternately and circumferentially disposed on one of the first surface and the second surface, a center of the circle located in the common pipe.

7. The apparatus of claim 1, wherein at least one of the first supply pipe and the second supply pipe is disposed inner than a peripheral portion of one of the first surface and the second surface.

8. The apparatus of one of claims 1 through 7, further comprising a third supply pipe connected to the second surface, and the common pipe and the third supply pipe are disposed on a same axis.

9. The apparatus of claim 8, further comprising a plasma generator installed between the buffer unit and the third supply pipe.

10. A non-transitory computer-readable recording medium storing a program causing a computer to perform: processing a substrate by supplying a first process gas and a second process gas into a process container via a supply system comprising: a common pipe connected to the process container wherethrough the first process gas and the second process gas flow; a buffer unit connected to an upstream side of the common pipe and having a width greater than a diameter of the common pipe; a first supply pipe wherethrough the first process gas flows, wherein the first supply pipe is connected to one of a first surface of the buffer unit where the common pipe is connected and a second surface of the buffer unit opposite to the first surface; and a second supply pipe wherethrough the second process gas flows, wherein the second supply pipe is connected to one of the first surface and the second surface, wherein each of the first supply pipe and the second supply pipe is installed outer than the common pipe, and a distance between the first surface and the second surface is shorter than a distance between a center axis of the common pipe and a center axis of the first supply pipe and a distance between the center axis of the common pipe and a center axis of the second supply pipe.

11. A method of manufacturing a semiconductor device, comprising: processing a substrate by supplying a first process gas and a second process gas into a process container via a supply system comprising: a common pipe connected to the process container wherethrough the first process gas and the second process gas flow; a buffer unit connected to an upstream side of the common pipe and having a width greater than a diameter of the common pipe; a first supply pipe wherethrough the first process gas flows, wherein the first supply pipe is connected to one of a first surface of the buffer unit where the common pipe is connected and a second surface of the buffer unit opposite to the first surface; and a second supply pipe wherethrough the second process gas flows, wherein the second supply pipe is connected to one of the first surface and the second surface, wherein each of the first supply pipe and the second supply pipe is installed outer than the common pipe, and a distance between the first surface and the second surface is shorter than a distance between a center axis of the common pipe and a center axis of the first supply pipe and a distance between the center axis of the common pipe and a center axis of the second supply pipe.
